(19) United States
(12) Patent Application Publication
(10) Pub. No.: US 2007/0183228 A1
(43) Pub. Date: Aug. 9, 2007

(54) CONTROL SIGNAL INTERFACE CIRCUIT FOR COMPUTER MEMORY MODULES

(76) Inventors: Robert D. Washburn, Malibu, CA (US); Robert F. McClanahan, Valencia, CA (US)

Correspondence Address: STEPTOE & JOHNSON LLP, 1330 CONNECTICUT AVENUE, NW, WASHINGTON, DC, 20036, US

(21) Appl. No.: 11/553,441

(22) Filed: Oct. 26, 2006

Related U.S. Application Data
(60) Provisional application No. 60/730,947, filed on Oct. 27, 2005.

(51) Int. Cl. G11C 29/00

(52) U.S. Cl. 365/200

(57) ABSTRACT

The present system is an electronic circuit designed for incorporation on high-speed computer memory modules such as DDR DIMMs. It couples control signals such as address bits, bank selects, enable and even clock signals between the module input connector and the memory devices. The circuit provides low propagation delay, fast rise and fall times with no overshoot or undershoot, and significantly improves timing control compared to memory modules of the present art. Capacitive loading on the motherboard is typically much less than that provided by a single memory device input and is independent of the number of memory devices per bank or the number of banks of memory devices on the memory module. For multiple memory modules connected to the memory bus, capacitive loading is essentially N times the equivalent loading for a single memory module.

### CROSS-REFERENCE TO RELATED APPLICATIONS

This application claims the benefit of U.S. provisional patent application No. 60/730,947, filed Oct. 27, 2005, which is herein incorporated by reference in its entirety.

### COPYRIGHT NOTICE

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### BACKGROUND OF THE SYSTEM

1. Field

The system relates to the field of computer memory modules and to wideband, high frequency amplifiers.

2. Background Art

Since the development of the personal computer, the characteristics and performance of the main memory has played a major role in defining the capabilities of the computers. From the beginning, the trend in the state of the art has been toward larger, faster main memory that is simultaneously consistent with the trend to ever-lower computer prices.

In the present art, a typical control signal is coupled through a series resistor (e.g. 22 ohms) to the memory devices (typically 8 or 9) through transmission line structures (typically 60-65 ohms). The form of memory device interconnection frequently depends on the location of the input signal pin on the DIMM (dual inline memory module), with daisy-chain connections very common. The present art loads the input control signal with the equivalent input capacitance of each of the memory devices input pins (typically 3-5 pf each) in parallel. The total capacitance has made it extremely difficult to achieve fast memory speeds. In fact, the control-signal rise and fall times are typically greater than the entire clock period, forcing increased latency and effectively limiting memory access speeds.

It may be observed that where memory clock speeds were once comparable to processor clock speeds, at present they are only about one tenth of that of the processor without even considering the impact of latency. As a result, it would be highly desirable to have a memory interface circuit which simultaneously provides for fast rise and fall times, consistent faster timing, low capacitive loading on the motherboard, the ability to add multiple banks of memory devices, without increasing capacitive loading, and the ability to parallel multiple memory modules on the memory bus without significantly impacting performance.

### SUMMARY OF THE SYSTEM

The present system is an electronic interface circuit that is located on the memory module and transmits a control signal from the input connector to the memory devices in one or more banks of the devices. The circuit provides very low and nearly constant capacitive loading of the signal that is independent of the number of memory devices and number of banks of memory devices on the module. Multiple DIMMs can be connected to the memory bus without significant loading of the control signals. The present system provides for substantially faster control signal rise and fall times with no overshoot or undershoot, low signal propagation delay, with predictable and substantially reduced control signal timing ranges. The present system can also be used to distribute the clock signal on the DIMM. It makes feasible driving all of the memory devices from a single clock input rather than the multiple inputs presently used.

The present system includes an alternate embodiment with a differential amplifier input that provides for simultaneous operation at substantially higher frequencies and lower power dissipation. Another embodiment uses an emitter follower input. The differential amplifier input also provides an interface for differential signals used in DDRII memory as well as for the clock signal. Differential input signals typically require differential outputs to interface with the memory ICs. Another embodiment includes the addition of a second base drive and output circuit to provide differential output capability.

Digital memory module drive is not the only electronic circuit application in which a low capacitance, high impedance input and the ability to drive capacitive loads must be realized in high frequency, wideband operation. High frequency operational amplifiers are analog devices that deviate from the classic description in that typically they have both input impedance that decreases with frequency (down to a hundred or even tens of ohms), and an output that requires significant resistive isolation to stably drive capacitive loads (of even a few picofarads). Video amplifiers are typically implemented with operational amplifiers.

One embodiment contains a variety of circuit topologies more typically associated with linear, analog, amplifier circuits than digital logic. These include differential amplifiers, cascode structures, level shifting, complimentary emitter follower output drive, and feedback. As a result, a linear, low distortion, wideband video amplifier embodiment can be easily realized by adjustment of bias and device DC operating points, value changes, and changes to the means by which ancillary circuit functions are implemented. The result is a video amplifier capable of very wide band operation with little gain variation and very low distortion. The input impedance is both higher and flatter than achieved with typical operational amplifiers. The output looks substantially like a voltage source and is capable of stably driving capacitive loads of tens of picofarads with minimal signal distortion.

### BRIEF DESCRIPTION OF THE DRAWINGS

FIG. 1 is an illustration of a typical waveform obtained with fast rise and fall time circuits of the present art.

FIG. 2 is an illustration of a typical waveform obtained with a fast rise and fall time circuit of the present system.

FIG. 3 is a block diagram illustrating an interface circuit of the present system applied to 1 address bit of a 2 bank DIMM.

FIG. 4 is a circuit diagram of a Control Signal Interface Circuit of the present system for implementing the interface circuit illustrated in FIG. 3.

FIG. 5 is a circuit diagram of a high performance embodiment of the Control Signal Interface Circuit of the present system.

FIG. 6 is a circuit diagram of a typical base drive network of the circuit of FIG. 5.

FIG. 7 is a circuit diagram of a typical feedback network of the circuit of FIG. 5.

FIG. 8 is a circuit diagram of a typical output network of the circuit of FIG. 5.

FIG. 9 is a circuit diagram of a typical output network of the Linear Interface Circuit Derivative-Low Distortion Video Amplifier.

FIG. 10 is a circuit diagram of a typical drive network of the Linear Interface Circuit Derivative-Low Distortion Video Amplifier.

FIG. 11 is a circuit diagram of a typical feedback network of the Linear Interface Circuit Derivative-Low Distortion Video Amplifier

### DETAILED DESCRIPTION OF THE SYSTEM

The present system is a high speed, low input capacitance interface circuit. It is directed toward coupling unidirectional control signals from the input connector of a memory module to the appropriate pins of the memory devices on the module. In the following description, numerous specific details are set forth to provide a more thorough description of embodiments of the system. It is apparent, however, to one skilled in the art, that the system may be practiced without these specific details. In other instances, well known features have not been described in detail so as not to obscure the system.

Discussion of the present system is directed toward application to 184-pin, 2.5 Volt (VDD)/2.5 Volt (VDDQ), Unbuffered, Non-ECC, Double Data Rate, Synchronous DRAM Dual In-Line Memory Modules (DDR SDRAM DIMMs), henceforth referred to as DIMMs. DIMMs are intended for use as main memory when installed in PCs and network servers. While the present discussion is directed toward 184-pin DIMM modules, the present system is not so limited and can be applicable to a wide variety of modular and non-modular memory configurations as well as many non-memory device interfaces.

The present system reduces the capacitive loading that a single memory bank DIMM module places on the unidirectional control signals received from the motherboard. In the present art, a typical control signal is coupled through a series resistor (22 ohms) to the memory devices (typically 8 or 9) through transmission line structures (typically 60-65 ohms). At best, the present art loads the input control signal with the equivalent input capacitance of each of the memory devices (typically 1.5-5 pf each) in parallel. The form of memory device interconnection frequently depends on the location of the input signal pin on the DIMM, with daisy-chain connections very common. The form of interconnection can significantly aggravate loading and timing problems. If a second memory bank is added to the DIMM, total capacitive loading is doubled. Since the impedance of the transmission line is unchanged, rise and fall times of the control signals will also double. Likewise, if the number of memory banks is increased from two to four, the rise and fall times will again double.

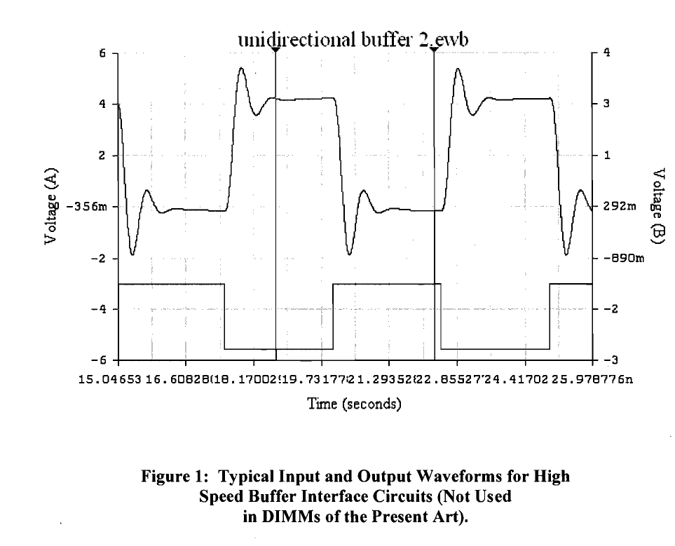

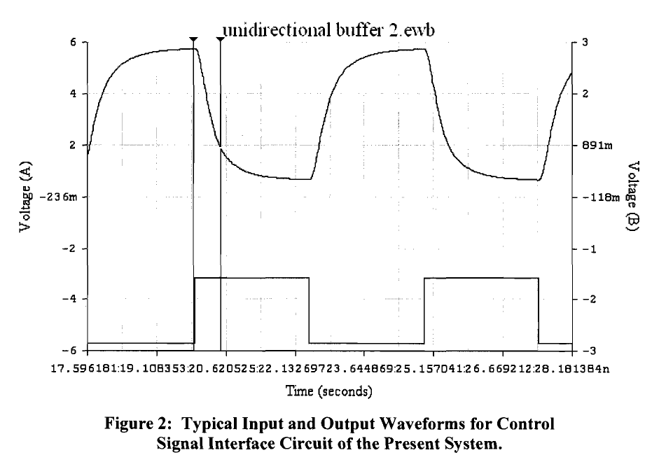

A potential problem with high-speed circuits is the tendency to have overshoot and undershoot as well as ringing on the output waveform. These are illustrated in FIG. 1, which shows the simulated performance of a typical high-speed buffer circuit. The comparable simulated waveform for one embodiment of the present system is shown in FIG. 2. Each figure includes both input and output waveforms. The circuit is driving the equivalent of 1 address bit on 4 memory devices (typically 1 device in each of 4 banks of memory devices).

It is well known that voltages applied to semiconductor devices may exceed the maximum dc voltage rating of the device for very short durations since the destructive breakdown processes do not have sufficient time to build up to a level at which physical damage occurs to the semiconductor. Memory devices used on DIMMs are no exception and are typically specified to allow 1.5 volt spikes for less than about 3 ns and for less than ⅓ of the clock period. Although the spikes will not damage the memory devices, overshoot cannot help but produce internal current flows and charge accumulations that differ from normal operation. The conditions are at best unspecified since the overshoot amplitude is unknown and uncontrolled, but are clearly not compatible with maximum device performance. It is known that many memory device types and DIMMs on which they are mounted exhibit enhanced performance at higher bias voltages (VDD). Many users are operating DIMMs at higher voltages than that specified for a 2.5V module. The preferred condition is no overshoot and is provided by the present system as illustrated in FIG. 2.

In addition to the DIMM address and control signals, the present system may be used to distribute the clock. The clock inputs are differential signals terminated on the DIMM in 120 ohms (for the 184 pin version to which this discussion is directed). The clock signal interface implemented with the present system may consist of a single input buffer with ground referenced input termination and generation of both the clock and inverse clock with out of phase output drivers, 2 interface circuits, or differential input version of the interface circuit. A benefit to clock distribution using the present system is that all memory devices on the DIMM may be driven from a single input clock signal. Use of a single clock input removes motherboard generated clock skew, improving timing margin on the DIMM by 100 ps or more.

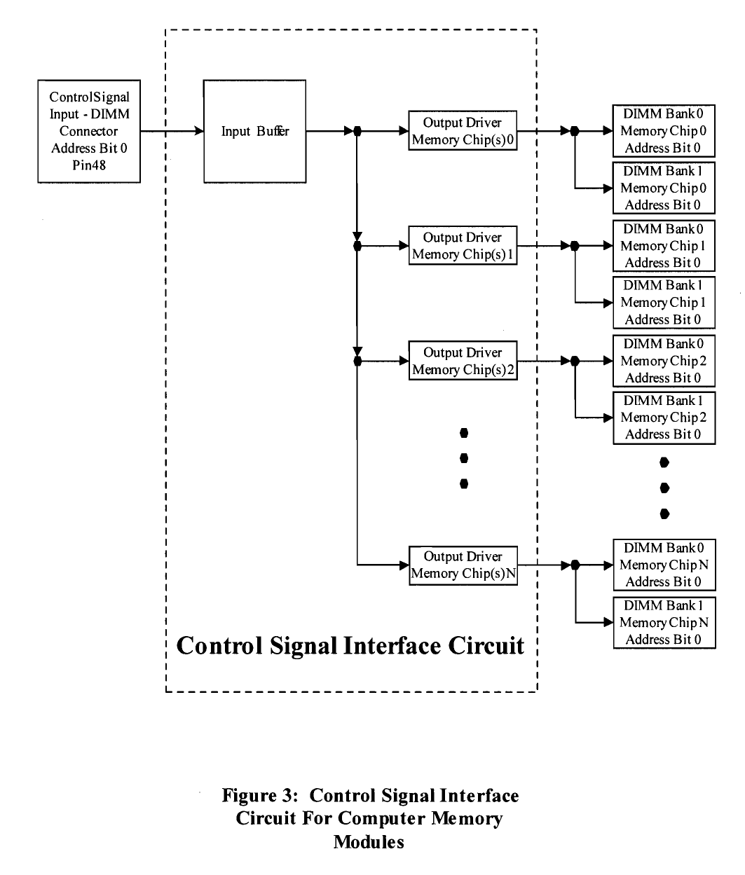

FIG. 3 shows a functional block diagram of one embodiment of the present system. The system includes two functional parts, the input buffer and the output driver(s). In general, there is one input buffer per DIMM and one output driver for each memory device position (the corresponding memory devices in all banks are typically driven from a single driver as illustrated in FIG. 2 for a 2 bank memory system). For meeting specific performance levels, selection of a particular embodiment depends largely on the current capacity and frequency characteristics of the transistors.

The output drivers, particularly on multi-bank DIMMs, are required to drive a large number of memory device inputs. Although theoretically only a single output driver is required, use of multiple drivers may be implemented since the drivers for all unidirectional control signals for each memory device position can be incorporated into an integrated circuit located near the memory device position. This approach can cost less than use of fewer, higher current devices.

A large number output drivers may stress the drive capability of the input buffer stage, it may lack adequate fanout capability. This can be overcome if a few intermediate (output driver type) stages are added to the input buffer circuit. Use of intermediate stages in the buffer has the added benefit of reducing its performance sensitivity to variations in the motherboard impedance characteristics. The intermediate stages should be packaged as part of the input buffer integrated circuit, typically located adjacent to the input pin on the DIMM connector. Regardless of the embodiment of the present system, adjustments to component values and bias points may be done to obtain optimized performance for individual memory device types and DIMM configurations.

The preferred embodiment uses bipolar junction transistors (BJTs) and technology for both the input buffer and output drivers. For the input buffer, a BJT provides lower loading on the motherboard memory bus. For the output drivers, use of BJTs provides for a reduction in gain near the end of the signal transition time as the device approach either ground or bias voltage. This characteristic coupled with wave shaping functions built into the circuit topology can both prevent overshoot or undershoot and allow the circuit designer to control transition times to optimize performance. Achievement of this requires none of the BJT base-collector junctions be forward biased.

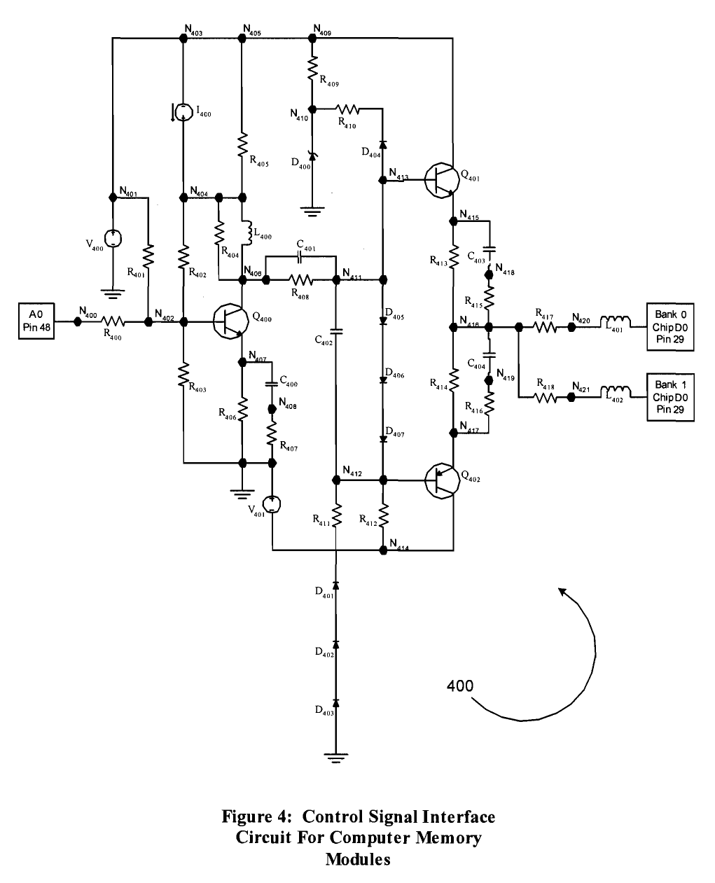

FIG. 4 is a circuit diagram of a preferred embodiment of the present system. Transistor Q400 and associated base, emitter, and collector circuitry comprise the input buffer. Resistor R408 and Capacitor C401 couple the output signal from the input buffer to the output driver portion of the circuit. The output driver is a push-pull structure formed by transistors Q401 and Q402 and capable of high current delivery during signal transitions. The current is primarily delivered through capacitors C403 and C404, at least until transitioning output(s) have passed the threshold for the new logic level.

Filtering, wave shaping, and clamping play an important role in achievement of the fast transition In addition to the C403 and C404 circuits, R404, R405, R406, R407, R408, R413, R414, R417, R418, L400, L401, L402, C401, C402, and C403 are part of the wave shaping function. Of particular interest are inductors L401 and L402. Typical values for these are 8 nH (assuming a memory device with 2 nH of lead inductance and 5 pf of input cap). Adding 8 nH (10 nH total with lead inductance) provides a damped resonant type interaction with the input capacitance of the memory device that effectively cancels a portion of the input capacitive loading.

Another important element of the present system involves I400, R404 and R405. Together, these devices simultaneously provide sufficient gain and current for high-speed pull-up and pull-down of Q400 collector (including adequate drive for the output driver) as well as stable biasing of the input buffer stage. Current source I400 implementation will depend on the detailed characteristics and requirements for an individual application.

The embodiment shown in FIG. 4 also includes clamping functions. Zener diode D400 generates a clamp reference voltage. Clamping is produced by diodes D401, D402, D403, and D404 along with resistors R410 and R411. Unlike typical clamp circuits that are designed to prevent over-voltage induced component failure, clamping in the present system contributes to preventing forward bias of transistor base-collector junctions. It also plays an important role in balancing the volt-second product across inductor L400 and its reset within desired timing parameters.

High Performance Control Signal Interface Circuit.

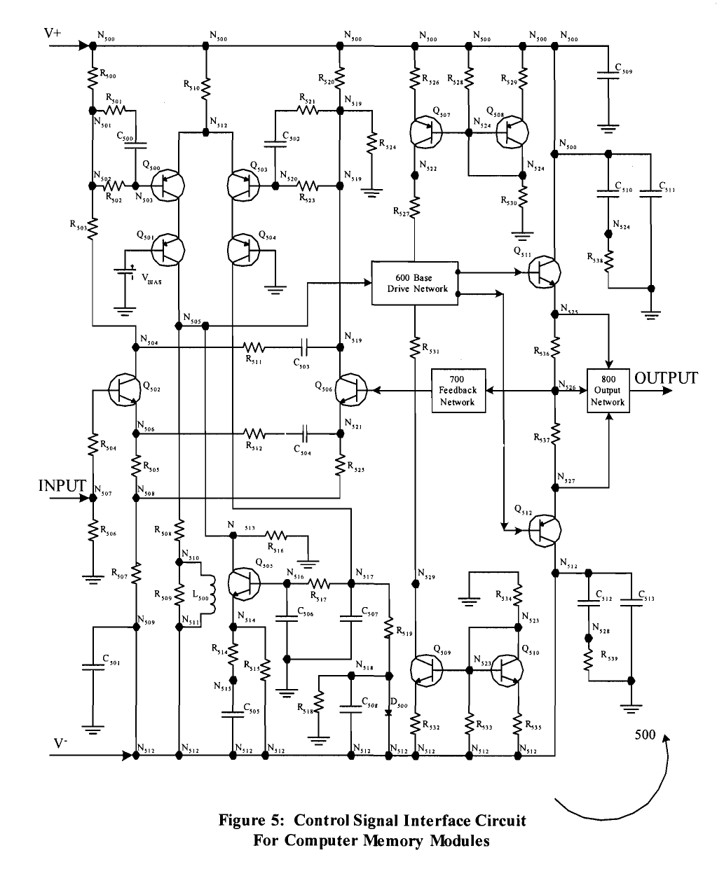

The control signal interface circuit shown in FIG. 4 provides substantial performance improvements over the present art. It will effectively allow memory module operation up to approximately twice the present clock frequency of 200 MHz (DDR400). Operation above this frequency is limited by the emitter follower input that has no active pull down. As operating frequency is increased with required corresponding reductions in input fall time, the emitter resistor must decrease in value (to lower RC time constant), significantly increasing power consumption. Power consumption due to the clamp diodes also represents an increasing problem with frequency. The embodiment of FIG. 5 can avoid these problems.

The approach taken is to employ a two-part circuit. The first part is a wideband amplifier, employing analog circuit structures with the following overall characteristics:

Minimal loading of the input signal.

Low propagation delay.

High gain with high slew rate capability.

Ability to drive high capacitance loads at high frequencies.

High stability.

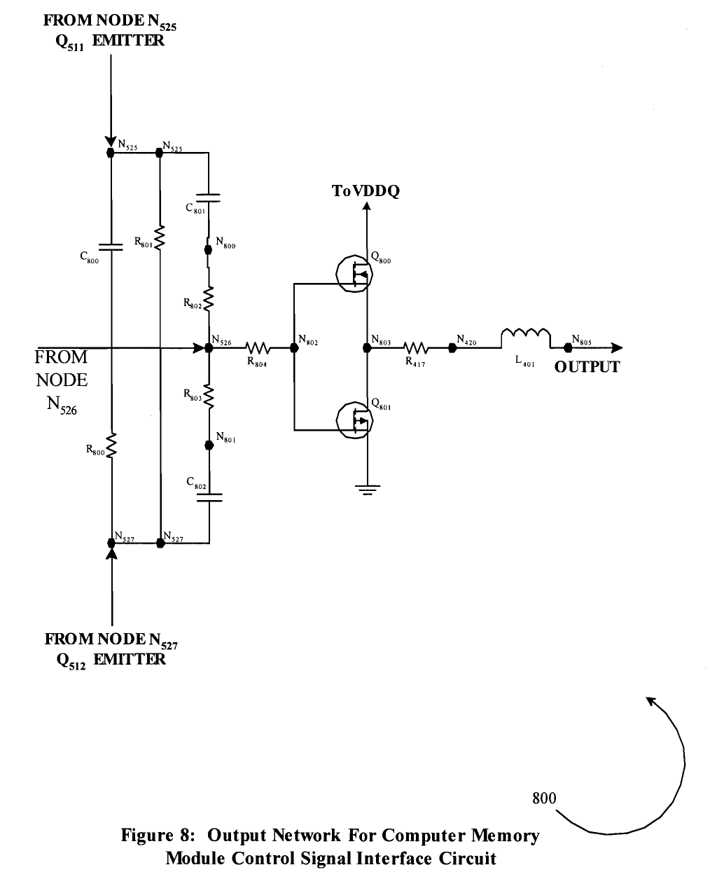

Gain flatness and low signal distortion are not significant concerns in this application. One issue associated with utilization of an analog amplifier in a digital application is the inability of the amplifier output signal to drive close to the bias supplies, a typical characteristic and requirement of digital signals. This difficulty is overcome by the second part of the circuit, a complimentary, totem pole FET drive circuit using low threshold FETs (Q800 and Q801 in FIG. 8). The FETs will simultaneously pull the output signal above and below the logic thresholds, drive the high total capacitance of the memory devices being driven, and have minimal propagation delay.

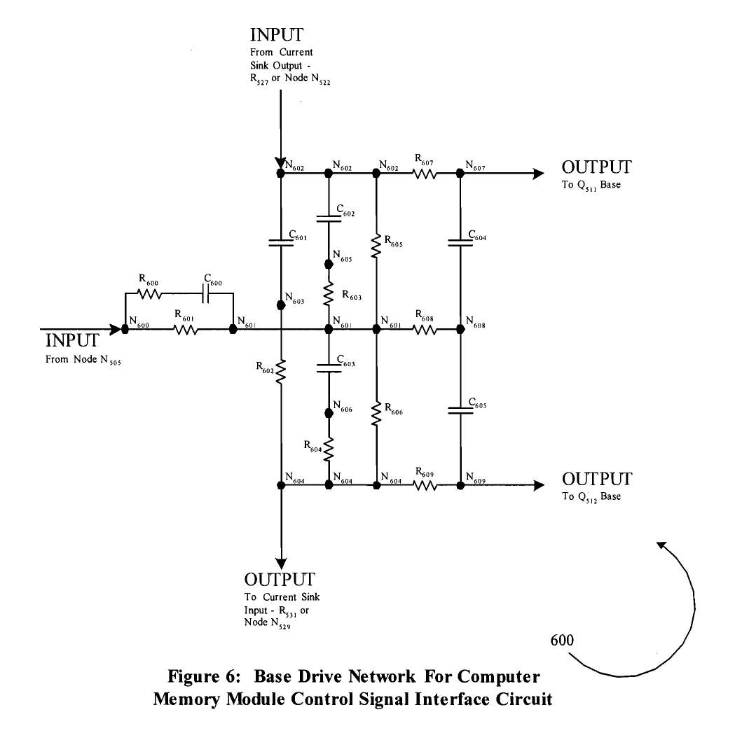

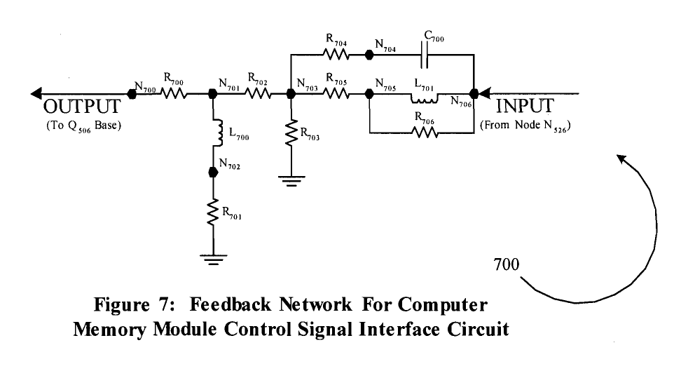

The amplifier illustrated in FIG. 5 is comprised of a differential amplifier input circuit (transistors Q502 and Q506 with associated passive components), as gain and level shift circuit comprised of PNP cascode differential amplifier (transistors Q500, Q501, Q503, and Q504 with associated passive components), an active pull-down network for the cascode amplifier (transistor Q505 with associated passive components), a current source (transistors Q507, Q508 with associated passive components), a current sink (transistors Q509, Q510 with associated passive components), a complimentary emitter follower drive circuit (transistors Q511, Q512 with associated passive components), and passive base drive (FIG. 6), feedback (FIG. 7), and output (FIG. 8) networks.

Differential Input to Differential Output Control Signal Interface Circuit.

One limitation of the embodiment of FIG. 4 is that it utilizes a single-ended input signal and produces a single-ended output signal. Although first generation DDR memory ICs primarily use single-ended signals, even they require differential clock inputs. Second generation DDR memory ICs employ differential signals exclusively, and future standards that are at present undefined may utilize differential signaling. Differential signaling could be accommodated by the use of 2 circuits of the embodiment of FIG. 4, but this introduces issues of matching rise and fall times, propagation delays, and offset voltages between the circuits as well as among signal pairs. All of these issues are aggravated as the operating frequency increases.

The embodiment of FIG. 5 is readily suited and preferred for use with differential signals. The second or inverted signal input requires the addition of two resistors. The first is of equal value and comparable to resistor R506 in that it both couples the inverted input signal to ground, and terminates the inverted input signal line if required. The second resistor is comparable to resistor R504 and couples the inverted input signal into the base of transistor Q506.

The differential output signal is provided by the addition of a second complimentary emitter follower output circuit identical to transistors Q511 and Q512 with their associated resistors and collector bias circuitry. Additional base drive and output networks (600 and 800), identical to those for the non-inverted signal must also be added. The added base drive network couples the collector of transistor Q504 to the second emitter follower output circuit. A second feedback network (700) is not generally required but may be implemented to provide closer matching of the differential signal elements. The danger is that use of feedback between the second emitter follower output network and the base of the non-inverting input transistor Q502 introduces an additional feedback loop that can interact with the first causing instability.

Control Signal Interface Circuit Linear Derivative for Low Distortion Video Amplifier.

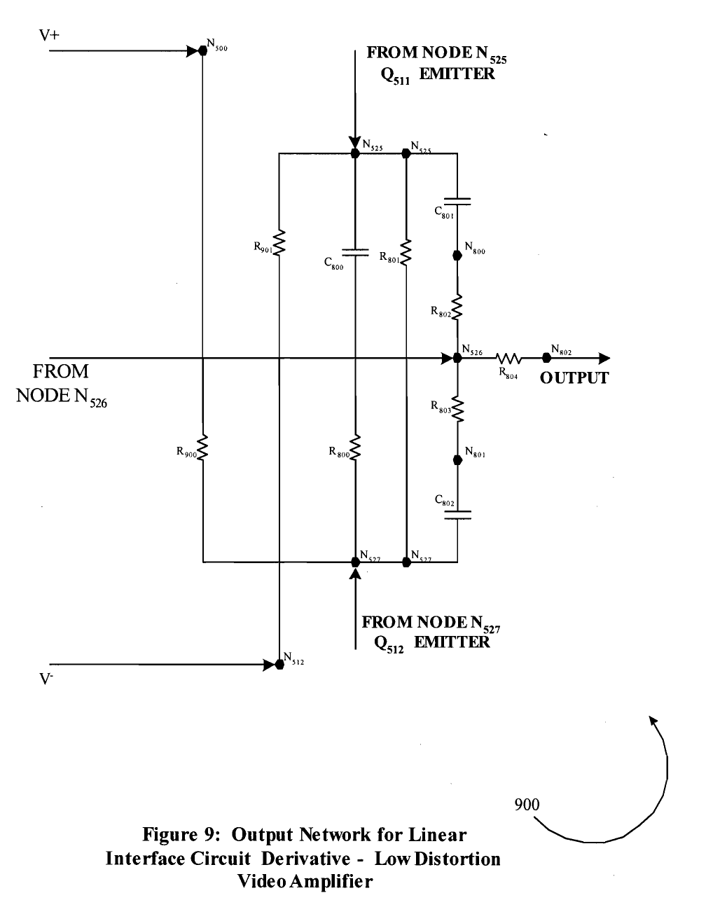

The control signal interface circuit of FIG. 5 is deliberately configured using circuits more typically associated with analog, linear amplifiers. As a result, a linear version for use as a wideband video amplifier can be realized with only minor modifications to the basic design. FIG. 5 is used as the baseline reference circuit for discussion of the video amplifier embodiment. FIGS. 9, 10, and 11 show the revisions to the output, base drive, and feedback networks respectively. There are 4 steps associated with this process with specific details of each depending on the performance requirements of the resulting video amplifier circuit and its application.

The first step is associated with increased bias voltage. Realization of low distortion in an amplifier typically requires that the semiconductor devices not be operated in regions of their characteristic curves that are highly non-linear. For example, silicon transistors typically require operation with a base-collector voltage above 2.5 volts. The bias voltages must be high enough to accommodate the cascode structure (2 transistors in series) plus the voltage drops through the resistors. Element values in the circuit must be adjusted accommodate the higher bias voltages as well as amplifier performance requirements.

The second step involves removal of components associated with and appropriate for speeding transitions and response time in the digital interface application, or which would adversely affect bandwidth, gain flatness and signal distortion of the video amplifier. These components would typically include resistors (R501, R503, R509, R511, R512, R514, R515, R516, R517, R518, R519, R521, R524, R603, R604, R608); capacitors (C500, C502, C503, C504, C505, C506, C507, C508, C602, C603, C604, C605); inductors (L500); diodes (D500); and transistors (Q504, Q505, Q800 and Q801). Removal of the active pull-down network for the PNP cascode circuit allows the removal of transistor Q504 and the grounding of the collector of transistor Q503.

The third step involves replacement of circuit functions with acceptable alternatives that eliminate semiconductors or other non-linear elements that can be a source of signal distortion. For example, the increased bias voltage opens the possibility for replacement of the output bias current source circuit (Q507, Q508, R526, R527, R528, R529, and R530) with a single resistor between the positive supply and the base drive network. The resistor value must simply be adequately large for the application or increased distortion will result. If an appropriate voltage higher than the nominal positive supply is available, the resistor may be coupled to it in order to further increase the resistor value. Similarly, a single resistor may replace the current sink circuit (Q509, Q510, R531, R532, R533, R534 and R535).

The fourth step involves additions to the circuitry to eliminate unwanted feedback paths and enhance stability, shape the gain and passband characteristics, and reduce harmonic and intermodulation distortion. Circuit additions can include but are not limited to the following:

1. Addition of resistors (2) between node N512 and the emitters of transistors Q500 and Q503. This converts the PNP structure from a true differential amplifier to an amplifier that allows control of both the current through the cascode structure as well as the contribution to the overall gain of the circuit.

2. Neutralization is a traditional technique for controlling positive feedback in amplifiers. In the present application, it can be implemented by adding a series resistor-capacitor network between the base and collector of the NPN input transistor Q502. A similar network may be implemented on Q506.

3. Complimentary emitter follower load stabilization and distortion reduction comprises the addition of resistors R900 and R901 of FIG. 9.

4. One or more series resistor-capacitor networks connected either in parallel with resistor R510 or from node N512 to ground.

5. Base of transistor Q501 connected to ground to provide a constant reference voltage that is independent of frequency. In addition, a resistor is added between the base and emitter of transistor Q501 to insure the base-emitter junction of transistor Q501 remains forward biased. An additional, large value resistor coupling the emitter of transistor Q501 to the positive supply voltage may be added to bleed in a small amount of current to maintain the condition if and when the current out of transistor Q500 is small.

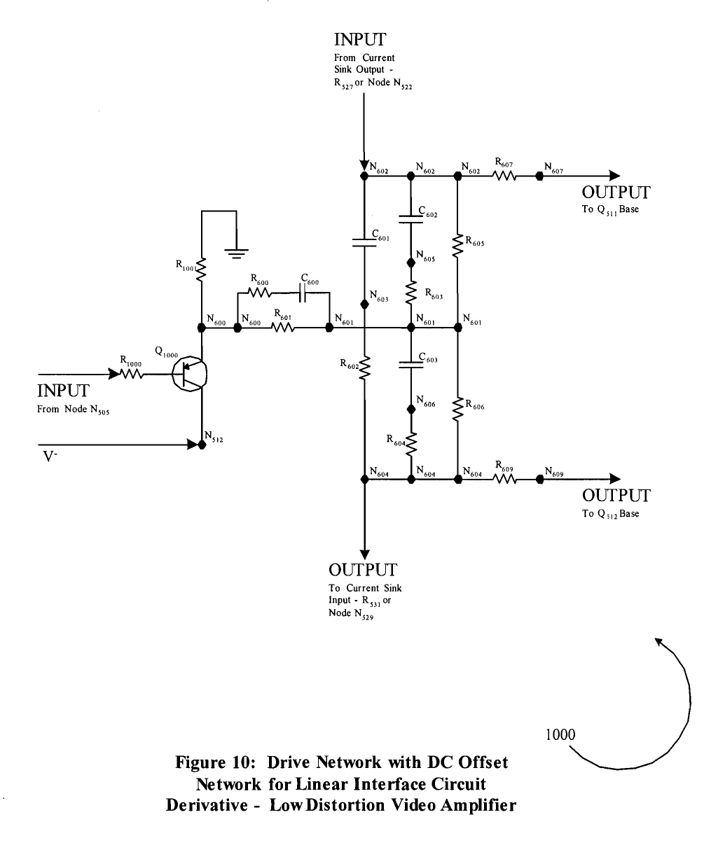

6. Drive signal buffer and DC offset control circuit provides gross setting of the output DC offset. In applications where a significant DC offset is required to match the characteristics and requirements of the output load circuitry, a portion of the output bias current is diverted from the current sink such that it passes through resistor R601 producing a DC voltage drop that translates to a negative offset on the output. The diverted current through resistor R601 is coupled to the negative supply via buffer transistor Q1000 of FIG. 10. Resistor R1001 provides current to maintain forward bias on the base-emitter junction of transistor Q1000 allowing coupling of the drive signal into node N600 and hence through the remainder of the drive circuit into the complimentary emitter follower output circuit. If a positive offset voltage is required, a buffer can be configured to source current that passes through resistor R601 in the opposite direction producing a positive offset. An alternative particularly useful in this situation is described in item (7) below.

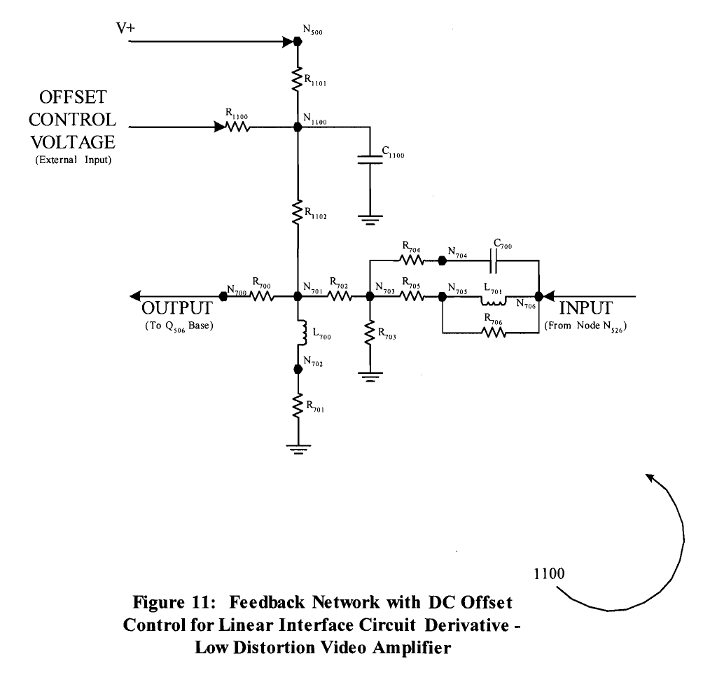

7. A fine DC offset adjustment control comprising resistors R1100, R1101, R102 and bypass filter capacitor C1100 of FIG. 11. An offset control voltage is applied to resistor R1100, which alters the dc current flowing from the positive supply through resistors R1101 and R1102 into the feedback network. The offset methods described in items (6) and (7) may be used individually, together, or not at all as required for a particular application.

Thus, a control signal interface circuit for computer memory modules has been described.

What is claimed is:

1. A control interface circuit comprising:
an input buffer receiving a control signal input;
a first output driver coupled to the input buffer and to a first memory bank to provide constant capacitive loading to the first memory bank.

2. The control interface circuit of claim 1 further including a second output driver coupled to the input buffer and to a second memory bank.

3. The control interface circuit of claim 2 wherein the memory bank is DIMM.

4. The control interface circuit of claim 3 wherein the control interface circuit coupled address bits, bank selects, enable and clock signals between the input buffer and the memory bank.

5. The control interface circuit of claim 4 wherein the circuit is implemented with bipolar junction transistors.

6. The control interface circuit of claim 5 wherein the circuit is implemented with emitter follower inputs.

7. The control interface circuit of claim 5 wherein the circuit is implemented with differential amplifiers.
